(19) United States
(12) Patent Application Publication
(10) Pub. No.: US 2008/0169878 A1
(43) Pub. Date: Jul. 17, 2008

(54) LOW LOSS COMBINER FOR NARROWBAND AND WIDEBAND RF SIGNALS

(76) Inventors: Giuseppe Resnati, Seregno (MI) (IT); Marco Santoniccolo, Milano (MI) (IT); Stefano Galli, Magenta (MI) (IT)

Correspondence Address: WOOD, HERRON & EVANS, LLP, 2700 CAREW TOWER, 441 VINE STREET, CINCINNATI, OH, 45202, US

(21) Appl. No.: 11/622,759

(22) Filed: Jan. 12, 2007

(51) Int. Cl. H01P 5/12; H03F 3/191; H01P 1/32

(52) U.S. Cl. 333/1.1; 333/100

(57) ABSTRACT

A combiner includes a circulator having a series of at least three sequential ports such that a signal input into a port is transmitted as an output at the next sequential port. A bandpass filter has a pass band and is coupled to a first port of the circulator such that a signal in the pass band that is input to the filter is output at a second port of the circulator. A third port of the circulator is configured to be coupled to an input signal that is out of the pass band such that a signal input at the third port is reflected as an output from the first port by the bandpass filter to then be output at the second port. The signals input at the first and third ports are combined at the second port. This configuration might be used in a cascaded fashion for combining multiple signals, together with low loss.

### FIELD OF THE INVENTION

This invention relates generally to the signal combination of multiple RF signals used in wireless communications and specifically to the combination of narrowband and wideband RF signals.

### BACKGROUND OF THE INVENTION

In wireless communication systems, such as cellular-based systems, multiple RF signals are combined for transmission through a single antenna or set of antennas. For example, at a cellular base station or site, multiple carrier signals, such as GSM carriers, for handling wireless communication traffic may be combined to be transmitted through the same antenna system. In such signal applications, it is always desirable to combine signals without significant signal loss or attenuation of the combined signals. Furthermore, it is desirable to minimize the cost and complexity of such signal combining systems.

In a typical GSM wireless system, it may be necessary to combine two or more GSM carriers. For low loss combining of narrowband carriers like GSM carriers, one conventional system uses the outputs of narrowband tunable filters (one filter for each GSM carrier). The outputs from the multiple narrowband filters are then electrically summed. An example of such a combiner design is illustrated in FIG. 1 wherein a combiner network 10 combines a first GSM carrier, GSM1 and a second carrier, GSM2. Each narrowband GSM carrier passes through a respective tunable narrowband filter 12, 14 and the carriers are electrically summed as indicated at junction 20 to be output to an antenna for transmission. For the purposes of isolation between the amplifiers providing the two carriers, each signal leg in the combiner 10 might use an isolator, such as the circulators 16, 18 illustrated in FIG. 1.

However, while the combiner design 10 of FIG. 1 provides a low loss signal combination for the two or more narrowband signals, it requires a tunable bandpass filter for each narrowband signal to be combined. Furthermore, it is applicable only for combining multiple narrowband signals.

In the progression of wireless communication technology and standards, it has become necessary to handle both narrowband and wideband signals and applications. The signal interface for third generation (3G) applications utilizes wideband signal technology such as wideband CDMA or W-CDMA. For example, applications such as UMTS applications, which are the 3G successors to GSM applications, make use of the W-CMDA protocol. Therefore, it is becoming desirable to have a single site, such as a cellular base station, that handles both wideband and narrowband applications. Such co-siting is becoming more frequent at wireless communication sites, and with co-siting, the combining of narrowband and wideband signals is mandatory.

To handle the combination of both narrowband and wideband signals, some systems employ hybrid couplers. For example, a combiner 22 is shown in FIG. 2 and has a W-CMDA input (WCDMA1) and a GSM input (GSM1) combined using hybrid coupler 22. The output is provided at port 24 of the coupler whereas the other port 26 is properly terminated. However, such a solution is lossy and effectively introduces a signal loss greater than 3 dB. This is generally unacceptable from a power consumption standpoint.

Therefore, there is still a need to provide a signal combiner that has low cost and low complexity. There is also a need for a low loss combiner able to combine not only narrowband signals, but also to combine narrowband and wideband signals, such as in co-siting applications.

### BRIEF DESCRIPTION OF THE DRAWINGS

FIG. 1 is a schematic view of a signal combiner.

FIG. 2 is a schematic view of another embodiment of a signal combiner for combining wideband and narrowband signals.

FIG. 3 is a schematic view of an embodiment of the invention for combining RF signals.

FIG. 4 is another schematic view of an alternative embodiment of invention for combining additional RF signals at a single output.

FIG. 5 is another schematic view of an alternative embodiment of invention for combining additional RF signals at a single output.

FIG. 6 is a schematic view of an embodiment of the invention illustrating multiple signal paths to the output.

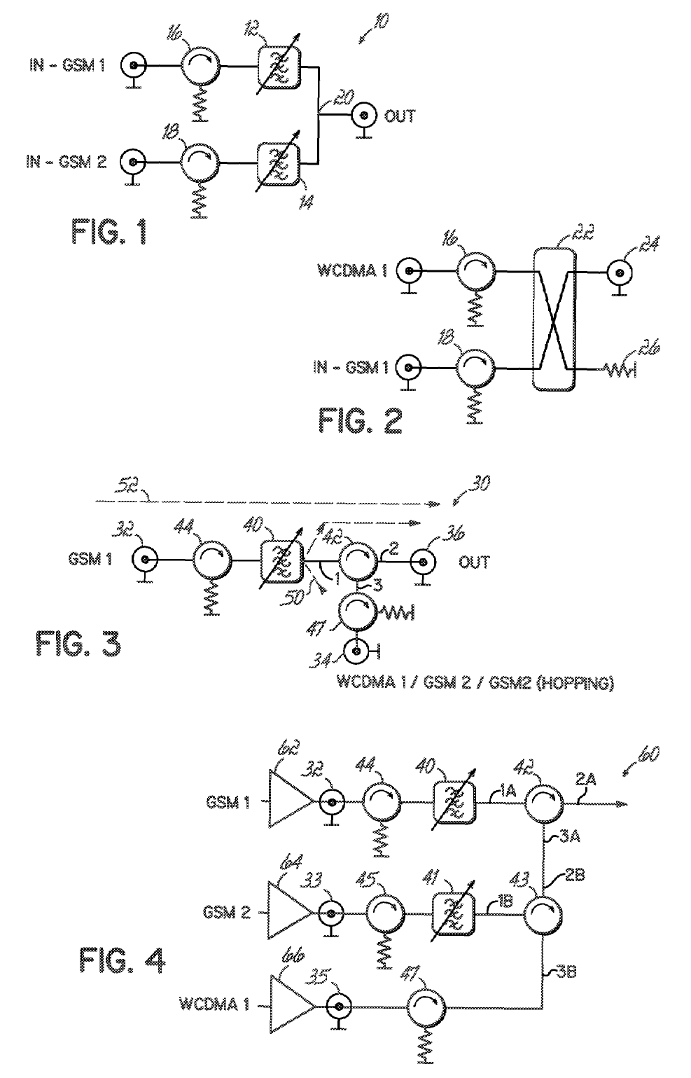

### DETAILED DESCRIPTION OF THE INVENTION

As noted above, it is desirable to combine RF signals, such as in wireless communication applications, using a low cost and low loss solution while reducing the complexity of the signal combiner. The present invention provides such a low loss combiner solution by eliminating components that had been utilized in prior solutions, and provides a low cost and simple, non-complex combiner. The inventive combiner is also expandable to accommodate additional signals to be combined. Furthermore, the inventive combiner is not only able to combine multiple narrowband signals, such as multiple GSM carriers, but also can handle wideband signals such as W-CDMA signals in a co-siting application.

Referring to FIG. 3, one embodiment of a combiner is illustrated in accordance with the principles of the present invention. Specifically, combiner 30 utilizes at least two input ports 32, 34 where a signal may be input for combination at a single output port 36. For example, two narrowband signals, such as narrowband GSM carriers GSM1 and GSM2 may be combined. Furthermore, a narrowband signal, such as GSM1, might be combined with a wideband signal, like the W-CDMA signal WCDMA1.

The narrowband signal GSM1 is introduced at signal port 32 and passes through a bandpass filter 40. Bandpass filter 40 has a defined pass band, which is a characteristic band of frequencies that are allowed through or will pass through the filter, as is understood by a person of ordinary skill in the art. Signals outside of the pass band are generally attenuated or rejected by the bandpass filter. The bandpass filter is preferably a tunable bandpass filter that may be tuned such that it will pass the signal input at port 32, such as signal GSM1.

The bandpass filter 40 is coupled to one input of a circulator 42. A circulator is a passive device with three or more ports in which the ports can be accessed in a sequential order, such that when a signal is input into a port, it is presented at the next sequential port. The first port of the circulator is also counted as following the last port in the sequential order. In one embodiment of the present invention as illustrated in FIG. 3, circulator 42 incorporates three sequential ports, although a circulator with a greater number of ports might also be utilized to facilitate the invention. Bandpass filter 40 is coupled to a first input port 1 of the circulator. That is, the output of the bandpass filter is coupled as an input-to-input port 1. A signal at signal port 32, which passes through the bandpass filter 40, and thus into the input port 1, will pass to or be presented as an output at the output port 2.

Generally, in the present invention, the circulator 44 has two input ports, ports 1 and 3, and has a single output port, port 2, wherein the signals from the input ports are combined according to the invention. Input port 3 of circulator 42 is coupled to the signal port 34 such that another input signal, such as an additional narrow band signal (GSM2) or a wideband signal (WCDMA1) is introduced into the input port 3 of circulator 42. The signal introduced at input port 3 is presented at the next sequential port, which is input port 1. Bandpass filter 40 is tuned or configured to pass the signal from signal port 32 to the input port 1 of circulator 42. The signal at input port 1 is then presented at output port 2 as noted above. However, the signal at signal port 34 would generally be outside or out of the pass band of filter 40. For example, a second narrowband signal, such as GSM2, might be outside of that pass band. Certainly, a wideband signal, WCDMA1, would be outside the pass band of the bandpass filter 40. Therefore, the input signal from the signal port 34 that is introduced at the circulator input port 3 and passed to the circulator input port 1 is rejected by filter 40. Since the signal from input port 3 is out of the pass band, it is reflected by the bandpass filter 40 at port 1 and then output to the output port 2 of circulator 42 as the next sequential port. Reference arrows illustrated by reference numeral 50 show the path of the signal input that is presented at signal port 34. Reference numeral 52 illustrates the path of the signal presented at signal port 32. Therefore, by the operation of combiner 30, multiple input signals at signal ports 32, 34 are combined at the single output port 36.

Combiner 30 may handle multiple narrowband signals (e.g., GSM1, GSM2), as illustrated as well as wideband signals (GSM1, WCDMA1), also illustrated in FIG. 3. The pass band filter 40 is tuned for passage of signal from port 32, but will reject other signals from port 34 such that the circulator re-routes the reflected signal to the single output port 36 to combine the signals from ports 32 and 34.

Prior to reaching the signal ports 32, 34, the respective input signals might be amplified and thus one or more GSM amplifiers and one or more WCMDA amplifiers (See FIG. 4) might be coupled to combiner 30. For the purposes of isolation, an isolator in the form of another circulator 44 with a terminated port might be coupled between input port 32 and the input to the bandpass filter 40 to provide isolation. Similarly, a circulator 47 would be utilized between port 34 and circulator 42, as shown in FIG. 3. However, the circulator/isolator 44 might be eliminated if a minimum distance or frequency spacing is provided between the carrier signals at the ports 32, 34.

Combiner 30 of the present invention reduces the complexity of the combiner as well as reduces its cost. Combiner 30 is low loss and only requires the tuning of a single bandpass filter 40, unlike other solutions as discussed above, that utilize a bandpass filter for each of the combined signals. The use of only one bandpass filter reduces not only the cost, but also the complexity of the combiner. Furthermore, combiner 30 may be utilized to combine both narrowband and wideband signals and introduces losses that are 2 dB lower than the hybrid combiner architecture discussed above with respect to FIG. 2.

In accordance with another aspect of the present invention, additional signals might be combined by cascading multiple combiners similar to combiner 30 together. For example, multiple GSM signals might be added together with a W-CDMA signal by cascading the inventive combiners as illustrated in FIG. 4. Combiner 60 incorporates multiple stages of the combiner as discussed above with respect to FIG. 3. Combiner 30 might be thought of as an elementary block, and thus combiner 60 incorporates multiple such combiner blocks. For the combiner illustrated in FIG. 4, like reference numerals will be utilized as shown in FIG. 3. That is, for combiner stage 30, a bandpass filter 40 is coupled to circulator 42 for combining signals. An additional cascaded notch combiner 31 is also coupled at circulator 42 and includes another bandpass filter 41 and another circulator 43. Signals to be combined are provided at signal ports 32, 33 and 35.

As illustrated in FIG. 4, the signal provided at signal ports 32 and 33 might be narrowband signals such as GSM1 and GSM2, respectively. The signal at signal port 35 might include a wideband signal such as WCDMA1. As illustrated in FIG. 4, amplifiers might be utilized to amplify the signals to be combined. For example, GSM1 and GSM2 might each include a single GSM carrier that would then be amplified by a single carrier power amplifier (SCPA) 62, 64, respectively. The wideband signal at signal port 35, such as the WCDMA1 signal, might include multiple carriers, such as two or three carriers, and thus would be amplified by a suitable multi-carrier power amplifier (MCPA) 66. As discussed with respect to the combiner 30 shown in FIG. 3, isolators in the form of circulators 44, 45 might be utilized in each of the notch combiner stages 30, 31 in order to provide isolation between the GSM amplifiers 62, 64 and the W-CDMA amplifier 66.

In the embodiment illustrated in FIG. 4, circulators 42, 43 each utilize three ports. For reference purposes, the three ports of the first circulator 42 are designated ports 1A, 2A and 3A, with ports 1A and 3A being input ports and port 2A being an output port. Similarly, the ports of circulator 43 are designated as ports 1B, 2B and 3B, with ports 1B and 3B being input ports and port 2B being an output port. As illustrated in FIG. 4, the output port 2B of the second circulator 43 is coupled to one of the input ports 3A of the first circulator 42. Similarly, if additional signals are to be combined with additional notch combiner stages, the additional circulators would be cascaded in that fashion.

Turning now to combiner 60, bandpass filters 40 and 41 might be considered first and second bandpass filters, although as discussed, if additional signals are added, additional bandpass filters may be necessary for each additional stage. Therefore, the present invention is certainly not limited to the embodiments illustrated in FIGS. 3 and 4 and may include additional stages for combining additional signals. The first bandpass filter 40 has a first pass band and is coupled to the first input port 1 A of circulator 42. Therefore, the signal provided at signal port 32, which passes through the bandpass filter 40, is provided as an output at the second port or output port 2A of circulator 42. Similarly, the second bandpass filter 41 is coupled to the first input port 1B of circulator 43 to provide a signal at the output port 2B of the first circulator.

The second port, or output port 2B of circulator 43, is coupled to the third port, or input port 3A of circulator 42. Since bandpass filter 40 has a pass band that is tuned for the input GSM1, the carrier of GSM2 is reflected by filter 40 and provided to the output port 2A of the first circulator 42 to thus combine with the carrier of GSM1. The additional signals that are to be combined take a somewhat similar path and migrate up to port 3A to be presented at the output of port 2A.

The input port 3B of circulator 43 is coupled with the signal port 35, which delivers the wideband signal WCDMA1 to port 3B. The WCDMA1 signal is out of band for both of the pass bands of the first and second bandpass filters, 40, 41. The signal at port 3B is presented at port 1B, and the out-of-band signal is reflected from port 1B to port 2B or, rather, to input port 3A of the first circulator 42. The signal is subsequently presented at port 1A (through port 3A). The signal at port 1A that is out of band with respect to filter 40 is reflected and presented at the output port 2A of circulator 42. In that way, the signals input at the first ports 1A, 1B to each of the circulators 42, 43, and at the third port 3B of the second circulator 43 are all combined as an output at the output port 2A.

For the purposes of isolation, circulators 44, 45 and 47 might be configured as isolators, as shown in FIG. 4.

The present invention might also be used for combining signals wherein at least one of the signals is a frequency-hopping signal. For example, some GSM applications might use a GSM carrier that jumps between several frequency channels at a high rate, whereas others of the GSM carriers are at a constant frequency channel. The technique is used to address random external disturbances and increase the robustness of the system. Since the tuning speed of a bandpass filter, such as filter 40, is too slow to adjust to the frequency hopping, which might be on the order of milliseconds, the frequency-hopping GSM signal is introduced at the wideband input port 34, as shown in FIG. 3.

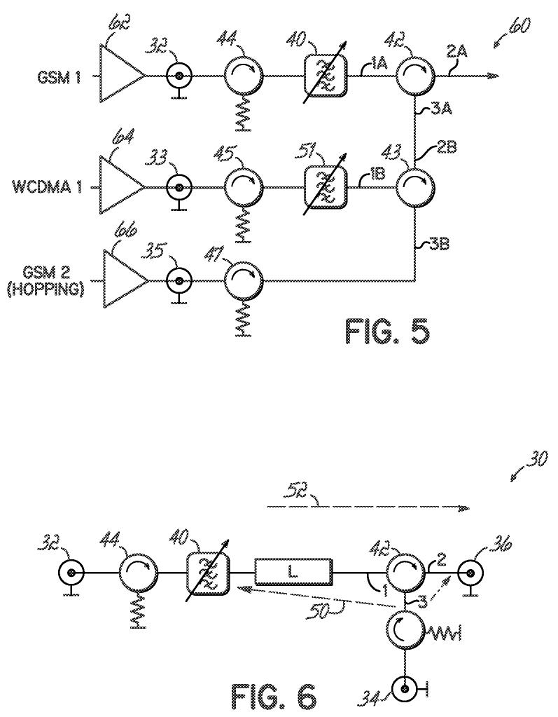

For combining a wideband signal with GSM carriers wherein one of the GSM carriers is used with a frequency-hopping technique, the circuit configuration of FIG. 5 might be used. In such a configuration, the wideband signal, such as WCDMA1 is input in the second leg at port 33, while the frequency-hopping GSM carrier is input at port 35. Generally, the W-CDMA bandwidth is between 5-15 MHz, but the band where GSM 2 will hop is not known. A wideband bandpass filter 51 is utilized in the second leg at port 33. The GSM 2 hopping signal is input to the wideband port and is reflected by filter 51, in accordance with the invention.

Accordingly, the present invention provides a low loss and low cost combiner with reduced complexity for combining not only multiple narrowband signals, but also combining narrowband and wideband signals, such as in co-siting applications. The combiner of the present invention might be incorporated directly into existing base station architecture by coupling it in the signal path to a duplexer, or other combiner, coupled to the antenna system for the base station. While the embodiments set forth herein use GSM and W-CDMA signals as examples, the present combiner is not limited to such signals. Signals from other signal formats and signal protocols might also be combined using the present invention.

In another aspect of the invention, an adjustable line element L might be used, as shown in FIG. 6, to reduce the overall insertion loss of the combined signal. Referring to FIG. 6, in actual operation, the circulator 42 has finite isolation in the counter-clockwise circulation and the signal proceeds in two ways, as shown. One path is between ports 3 and 1, plus the reflection from the filter and the path between ports 1 and 2. The other path is between the ports 3 and 2. Since the signals have a vectors sum at port 2, varying the phase of the signal in the 3 to 1 to 2 path may reduce the overall loss. In accordance with another aspect of the present invention, the effective line length of element L (e.g., a piece of coax cable or other conductor) might be varied and empirically determined in order to affect the phase of the signal in the 3-1-2 path so that sum of the loss of the path 3-1 and the path 1-2 is reduced below the theoretical value for that loss. The element L might be a separate element or it might be designed into the bandpass filter, and the filter would then be optimized in order to achieve the desired phase adjustment. The element L is thus coupled between the bandpass filter and the first port of the circulator for varying the phase of the signal at the first port.

Although FIG. 6 shows a single leg combiner, the elements L might be used for the multi-leg embodiments, as shown in FIGS. 4 and 5 to achieve similar results in reducing loss in the combiner.

Thus, while the present invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. Thus, the invention in its broader aspects is therefore not limited to the specific details, representative apparatus and method, and illustrative example shown and described. Accordingly, departures may be made from such details without departing from the spirit or scope of applicants' general inventive concept. For example, the exemplary feed- forward amplifier system described herein has focused on digital filters implemented by switching capacitors to ground, aka digitally commutated filter). However, the principles of the present invention are applicable to other digital filters as well.

What is claimed is:

1. a combiner comprising:
a circulator having a series of at least three sequential ports such that a signal input into a port is transmitted as an output at the next sequential port;
a bandpass filter having a pass band and coupled to a first port of the circulator such that a signal in the pass band that is input to the filter is output at a second port of the circulator;
a third port of the circulator configured to be coupled to an input signal that is out of the pass band such that a signal input at the third port is reflected as an output from the first port by the bandpass filter to then be output at the second port;
wherein the signals input at the first and third ports are combined at the second port.

2. The combiner of claim 1 further comprising another circulator coupled to at least one of the bandpass filter input or the third port to act as an isolator.

3. The combiner of claim 1 wherein the bandpass filter is tunable.

4. The combiner of claim 1 wherein the bandpass filter is configured to pass a narrowband signal.

5. The combiner of claim 4 wherein the narrowband signal includes a narrowband GSM carrier.

6. The combiner of claim 1 wherein the bandpass filter is configured to reject a wideband signal and thus reflect the wideband signal to the first port.

7. The combiner of claim 6 wherein the wideband signal includes at least one of a W-CDMA signal or a frequency-hopping GSM signal.

8. The combiner of claim 1 further comprising a line element coupled between the bandpass filter and the first port of the circulator for varying the phase of the signal at the first port.

9. A combiner comprising:
a first circulator and at least a second circulator, each having a series of at least three sequential ports such that a signal input into a port of the circulator is transmitted as an output at the next sequential port;
a first bandpass filter having a first pass band and coupled to a first port of the first circulator such that a signal in the first pass band that is input to the first bandpass filter is output at a second port of the first circulator;
a second bandpass filter having a second pass band and coupled to a first port of the second circulator such that a signal in the second pass band that is input to the second bandpass filter is output at a second port of the second circulator;
the second port of the second circulator coupled to the third port of the first circulator such that a signal from the second port of the second circulator that is outside of the first pass band is reflected as an output from the first port of the first circulator to then be output at the second port of the first circulator;
a third port of the second circulator configured to be coupled to an input signal that is out of band for both the first and second pass bands, such that a signal input at the third port of the second circulator is reflected as an output from the first port of the second circulator by the second bandpass filter and then is reflected as an output from the first port of the first circulator by the first bandpass filter to then be output at the second port of the first circulator;
wherein the signals input at the first ports of each of the circulators and at the third port of the second circulator are all combined as an output at the second port of the first circulator.

10. The combiner of claim 9 further comprising another circulator coupled to at least one of an input of the first or second bandpass filters or the third port of the second circulator to act as an isolator.

11. The combiner of claim 9 wherein the bandpass filter is tunable.

12. The combiner of claim 9 wherein the bandpass filters are configured to pass narrowband signals.

13. The combiner of claim 12 wherein the narrowband signals include at least one narrowband GSM carrier.

14. The combiner of claim 9 wherein at least one of the bandpass filters is configured to pass a wideband signal.

15. The combiner of claim 12 wherein the first bandpass filter is configured to pass a first GSM carrier, and the second bandpass filter is configured to pass a second GSM carrier, different from the first GSM carrier.

16. The combiner of claim 9 wherein the bandpass filters are configured to reject a wideband signal and thus reflect the wideband signal to the second port of the respective circulator.

17. The combiner of claim 16 wherein the wideband signal includes a W-CDMA signal.

18. The combiner of claim 9 wherein the third port of the second circulator is configured to be coupled to a wideband signal as an input signal.

19. The combiner of claim 9 wherein the first bandpass filter is configured to pass a narrowband signal and the second bandpass filter is configured to pass a wideband signal.

20. The combiner of claim 9 wherein the third port of the second circulator is configured to be coupled to a frequency-hopping signal.

21. A method for combining signals comprising:
filtering a first input signal with a bandpass filter having a pass band;
introducing the filtered first input signal to a first port of a circulator having a series of at least three sequential ports such that a signal input into a port is transmitted as an output at the next sequential port;
the first input signal at the first port being output at the second port;
introducing a second input signal to a third port of the circulator such that the second input signal is output at the first port;
reflecting the second input signal with the bandpass filter at the first port so that the second input signal is then output at the second port;
wherein the first and second input signals are combined at an output at the second port.

22. The method of claim 21 further comprising introducing at least one of the first input signal or the second input signal to another circulator prior to the bandpass filter, to isolate the first and second input signals.

23. The method of claim 21 wherein the bandpass filter is configured to pass a narrowband signal.

24. The method of claim 23 wherein the narrowband signal includes a narrowband GSM carrier.

25. The method of claim 21 wherein the bandpass filter is configured to reject a wideband signal and thus reflect the wideband signal to the first port.

26. The method of claim 25 wherein the wideband signal includes at least one of a W-CDMA signal or a frequency-hopping GSM signal.

27. The method of claim 21 further comprising varying the phase of the signal at the first port of the circulator.

28. A method for combining signals comprising:
filtering a first input signal with a first bandpass filter having a first pass band;
introducing the filtered first input signal to a first port of a first circulator having a series of at least three sequential ports such that a signal input into a port is transmitted as an output at the next sequential port;
the first input signal at the first port being output at the second port of the first circulator;
filtering a second input signal with a second bandpass filter having a second pass band;
introducing the filtered first input signal to a first port of a second circulator having a series of at least three sequential ports such that a signal input into a port is transmitted as an output at the next sequential port;
the second input signal at the first port being output at the second port of the second circulator;
coupling the second port of the second circulator to the third port of the first circulator such that a signal from the second port of the second circulator that is outside of the first pass band is reflected as an output from the first port of the first circulator to then be output at the second port of the first circulator;
introducing a third input signal to a third port of the second circulator such that the any third input signal that is out of band for both the first and second pass bands, is reflected as an output from the first port of the second circulator by the second bandpass filter and then is reflected as an output from the first port of the first circulator by the first bandpass filter to then be output at the second port of the first circulator;
wherein the first and second input signals and the third input signal are all combined as an output at the second port of the first circulator

29. The method of claim 28 further comprising introducing at least one of the first, second or third input signals to another circulator prior to the first bandpass filter, to isolate the signals from each other.

30. The method of claim 28 further comprising introducing the second input signal to another circulator prior to the second bandpass filter, to isolate the second and third input signals.

31. The method of claim 28 wherein the bandpass filters are configured to pass narrowband signals.

32. The method of claim 28 wherein at least one of the bandpass filters is configured to pass a wideband signal.

33. The method of claim 31 wherein the narrowband signals include at least one narrowband GSM carrier.

34. The method of claim 31 wherein the first bandpass filter is configured to pass a first GSM carrier, and the second bandpass filter is configured to pass a second GSM carrier, different from the first GSM carrier.

35. The method of claim 28 wherein the bandpass filters are configured to reject a wideband signal and thus reflect the wideband signal to the second port of the respective circulator.

36. The method of claim 35 wherein the wideband signal includes a W-CDMA signal.

37. The method of claim 28 wherein the first bandpass signal is configured to pass a narrowband signal and the second bandpass filter is configured to pass a wideband signal.
